(19) United States
(12) Patent Application Publication
(10) Pub. No.: US 2007/0011544 A1
(43) Pub. Date: Jan. 11, 2007

(54) Reprogramming of tester resource assignments

(76) Inventors: Hsiu-Huan Shen, Saratoga, CA (US); Jianxiang Chang, Milpitas, CA (US); Ben Rogel-Favila, Santa Clara, CA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/153,180

(22) Filed: Jun. 15, 2005

(51) Int. Cl. G01R 31/28; G06F 11/00

(52) U.S. Cl. 714/742

(57) ABSTRACT

A method including creating a mapping file and a package test program for testing an electronic package. The package comprises a device. The package test program comprises source code for a device test program for testing the device and source code from the mapping file. The device test program source code comprises a reference to a device pin identifier which identifies an associated device pin. Each identified device pin is attached to an associated package pin. Each package pin is identified by a package pin identifier. The mapping file redefines each device pin identifier to be the associated package pin identifier in the package test program. At least one instruction in the package test program created from the device test program source code is configured to attach a tester resource to one of the package pins, and to appropriately activate the tester resource.

### BACKGROUND

Test and measurement functions are an important part of modern product development and manufacture. There are a variety of test and measurement techniques that can be used for such purposes.

These techniques include manually performing given tests or sets of tests. Another technique is to employ an interactive soft front panel on a computer monitor, thereby providing the user a virtual instrument front panel. However, in both of these techniques, typically none of the testing steps are remembered by the measurement system for repeated use, no test automation occurs, and in the latter case, the user merely uses the computer for control of the instrument. While useful as exploratory tools, these techniques are ineffective when the test or tests must be repeated as product design changes are made, when multiple prototypes are built, when the test environment is large scale, or when the test is to be repeated on multiple parts as is the case in a modern manufacturing process.

To overcome the limitations of manual testing, the instruments that perform these tests can be combined into systems referred to as automatic test equipment (ATE) test systems which can be programmed to automatically perform a number of selected tests on particular units. The test programs that perform such tests can be executed by an ATE system on its central processing unit (CPU) to control one or more instruments. Such programs are typically inflexible. They are also time consuming and expensive to develop, as well as to change.

### SUMMARY

In a representative embodiment, a method is disclosed. The method comprises creating a mapping file and creating a package test program for testing an electronic package. The electronic package comprises a device, and the package test program comprises source code for a device test program for testing the device and source code from the mapping file. The device test program source code comprises at least one reference to at least one device pin identifier, and each device pin identifier identifies an associated device pin on the device. Each identified device pin is attached to an associated package pin on the electronic package, and each package pin is identified by a package pin identifier. The mapping file redefines each device pin identifier in the device test program source code to be the associated package pin identifier in the package test program, and at least one instruction in the package test program created from the device test program source code is configured to attach a tester resource to one of the package pins, and to appropriately activate the tester resource.

Other aspects and advantages of the representative embodiments presented herein will become apparent from the following detailed description, taken in conjunction with the accompanying drawings.

### BRIEF DESCRIPTION OF THE DRAWINGS

The accompanying drawings provide visual representations which will be used to more fully describe various representative embodiments and can be used by those skilled in the art to better understand them and their inherent advantages. In these drawings, like reference numerals identify corresponding elements.

FIG. 1 is a drawing of a block diagram of a test system as described in various representative embodiments.

FIG. 2 is a drawing of a block diagram of a multi-chip package as described in various representative embodiments.

FIG. 3 is a drawing of a graphical user interface (GUI) for mapping device pin identifiers into package pin identifiers of a package as described in various representative embodiments.

FIG. 4 is a drawing of a flow chart of a method for device pin identifier translation to package pin identifier for a unit under test as described in various representative embodiments.

FIG. 5 is a drawing of another block diagram of the test system as described in various representative embodiments.

FIG. 6 is a drawing of a block diagram of a component configuration used in creating a package test program as described in various representative embodiments.

FIG. 7 is a drawing of a block diagram of another component configuration used in creating a package test program as described in various representative embodiments.

### DETAILED DESCRIPTION

As shown in the drawings for purposes of illustration, novel techniques are disclosed herein for testing multi-chip packages (MCPs). Previous techniques for testing multi-chip packages have required that programs written for wafer test be rewritten for use at package test.

The emergence of the multi-chip package is a recent advance in semiconductor technology. A multi-chip package typically contains several individual semiconductor devices some of which can be duplicates of a given device. Integrated circuit (IC) test engineers create test programs to test individual die during wafer test. Later individual die are packaged into the multi-chip packages. Testing the multi-chip packages requires updating the assignment of device pins to tester resources in the test program developed for individual die at wafer test. This is an expensive and time consuming process.

In representative embodiments, a method and tool are disclosed for rearranging tester resources without requiring modification to the test program written for the wafer test. Generating pin mapping files based on user input removes the need to change the wafer test programs. A window can be provided to the user in which the user can enter the relationship between individual device pins/pin groups and multi-chip package pins/pin groups. With this information a test controller software program can generate mapping files that can be used to modify the wafer test program pin assignments.

In the following detailed description and in the several figures of the drawings, like elements are identified with like reference numerals. While the following discussion is primarily in terms of multi-chip packages, it will be recognized by one of ordinary skill in the art that other units including packages comprising other packaged devices and other multi-chip packages fall within the scope of the appended claims.

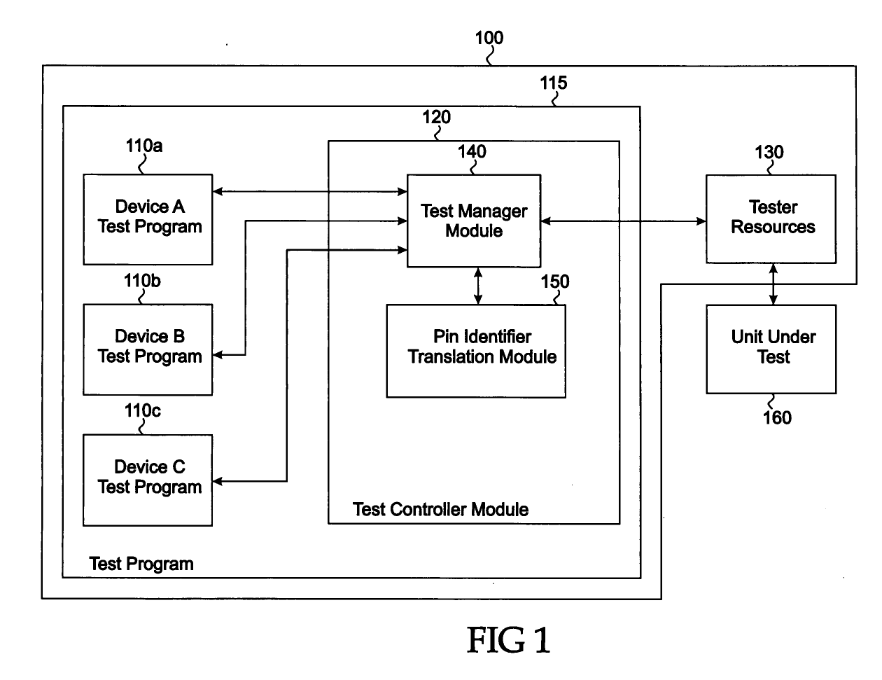

FIG. 1 is a drawing of a block diagram of a test system 100 as described in various representative embodiments. In the example of FIG. 1, the test system 100 comprises a test program 115, also referred to herein as a package test program 115, and tester resources 130. The test program 115 comprises a test controller module 120 and a number of test programs. The number of test programs in the test program 115 is application dependent. In the example of FIG. 1, three test programs are shown labeled as device A test program 110a, device B test program 110b, and device C test program 110c which are collectively referred to as device test programs 110. The device test programs 110 are the test programs that would be used at wafer test for integrated circuit chips or other devices of three separate types. The test controller module 120 comprises a test manager module 140 and a pin identifier translation module 150.

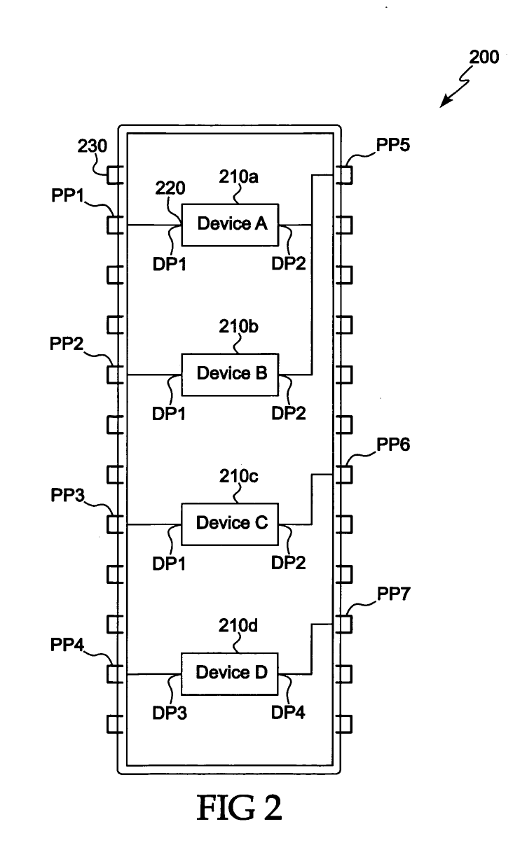

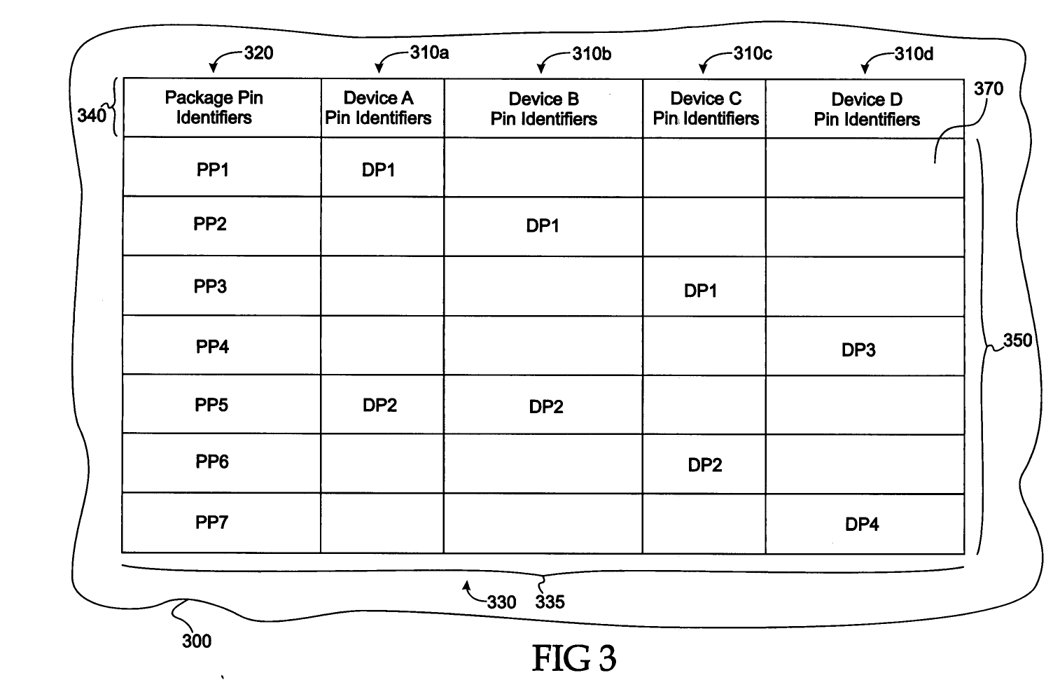

In operation, the test manager module 140 controls the flow of tests which the test system 100 performs on a unit under test 160 and the appropriate assignment of tester resources 130. The tester resources 130 could comprise various instruments for applying stimulus signals, such as voltage and current at selected frequencies or known bit patterns at selected clock rates, at defined test pins on the unit under test 160 and detecting/measuring resultant responses by the unit under test 160 to the applied stimulus at the same or other test pins. The function of the pin identifier translation module 150 will be explained more fully in connection with the discussion of FIGS. 2 and 3.

FIG. 2 is a drawing of a block diagram of a multi-chip package 200 as described in various representative embodiments. In the representative example of FIG. 2, the multi-chip package 200, also referred to herein as package 200 and as electronic package 200, comprises a first device 210a (device A), a second device 210b (device B), a third device 210c (device C), and a fourth device 210d (device D) which are referred to collectively as devices 210 and which could be packaged or unpackaged integrated circuit (IC) chips 210. As will be recognized by one skilled in the art, devices 210 could also be multi-chip packages, discrete packaged devices, or the like.

In a representative example, the first device 210a, second device 210b, and third device 210c could be replicas of the same device. In this example, they are all replicas of device A which is tested by device A test program 110a of FIG. 1 the fourth device 210d is a replica of device B which could be tested by device B test program 110b of FIG. 1. For this application, the device C test program 110c would not be included.

Each device 210 shown in FIG. 2 comprises at least one device pin 220 for the purposes of application of power and/or input signal(s) and/or the reception of output signal(s) to/from the device 210. For clarity of illustration, only one of the device pins 220 is indicated by its identifying number on one device 210 in FIG. 2. Also, for clarity of illustration, each device 210 is shown with only two device pins 220. In other embodiments, some devices 210 may have additional device pins 220 which are attached to other package pins 230 and/or to other devices 210 internally to the package 200. In still other embodiments, some devices 210 may not have any of their device pins 220 attached externally to a package pin 230.

Each device pin 220 shown in FIG. 2 is attached to one of the package pins 230 on the package 200. The package pins 230 are for the purposes of application of power and/or input signal(s) and/or the reception of output signal(s) to/from the package 200. For clarity of illustration, only one of the package pins 230 is indicated by its identifying number on the package 200 in FIG. 2. Some package pins 230 may not be connected to any of the devices 210 in the package 200.

The identifiers DP1, DP2, DP3, and DP4 associated with certain of the device pins 220, and the identifiers PP1, PP2, PP3, PP4, PP5, PP6, and PP7 associated with certain of the package pins 230 will be discussed in connection with the discussion of FIG. 3.

FIG. 3 is a drawing of a graphical user interface (GUI) 300 for mapping device pin identifiers 310 into package pin identifiers 320 of a package 200 as described in various representative embodiments. In FIG. 3, the user can use the graphical user interface 300 with a mouse (not shown) and a keyboard (not shown), for example, to input and/or change identifiers for mapping device pin identifiers 310 to package pin identifiers 320 in a table 330. The table 330 of FIG. 3 comprises a title row 340, a package column comprising the package pin identifiers 320, and a column for each of the four devices 210 shown in FIG. 2 comprising the device pin identifiers 310 for the associated device 210 with a set of rows 350 (one row for each package pin identifier 320).

The intersection of one of the rows 350 in the set and a column 360 is a cell 370 of the table 330. For clarity of illustration, only one of the cells 370 is indicated by its identifying number in FIG. 3.

In the table 330 of FIG. 3, for device A 210a, the device pin 220 identified as device pin identifier 310 DP1 is connected to the package pin 230 identified as and mapped into package pin identifier 320 PP1, and the device pin 220 identified as device pin identifier 310 DP2 is connected to the package pin 230 identified as and mapped into package pin identifier 320 PP5; for device B 210b, the device pin 220 identified as device pin identifier 310 DP1 is connected to the package pin 230 identified as and mapped into package pin identifier 320 PP2, and the device pin 220 identified as device pin identifier 310 DP2 is connected to the package pin 230 identified as and mapped into package pin identifier 320 PP5; for device C 210c, the device pin 220 identified as device pin identifier 310 DP1 is connected to the package pin 230 identified as and mapped into package pin identifier 320 PP3, and the device pin 220 identified as device pin identifier 310 DP2 is connected to the package pin 230 identified as and mapped into package pin identifier 320 PP6; and for device D 210d, the device pin 220 identified as device pin identifier 310 DP3 is connected to the package pin 230 identified as and mapped into package pin identifier 320 PP4, and the device pin 220 identified as device pin identifier 310 DP4 is connected to the package pin 230 identified as and mapped into package pin identifier 320 PP7.

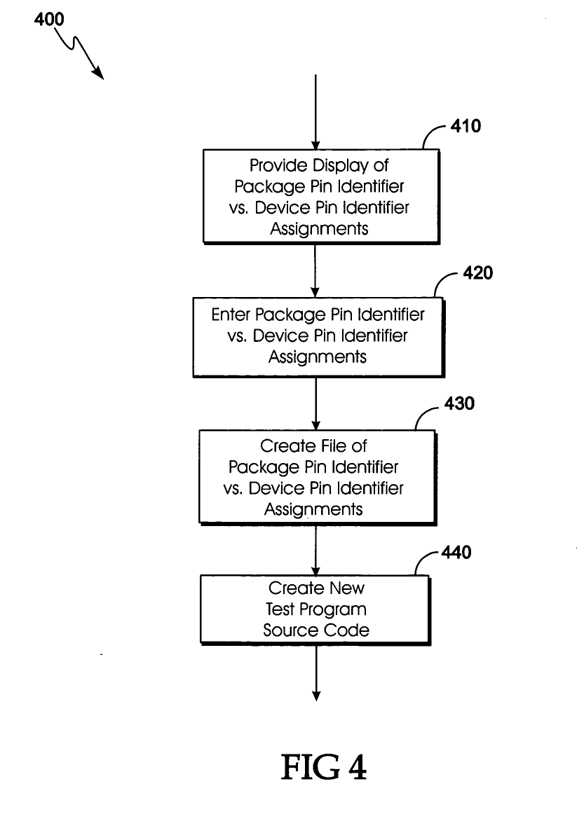

FIG. 4 is a drawing of a flow chart of a method 400 for device pin identifier 310 translation to package pin identifier 320 for a unit under test 160 as described in various representative embodiments. In the representative embodiment of FIG. 4, the unit under test 160 is typically a multi-chip package 160 or a multi-device package 160. In block 410 of FIG. 4, a graphical user interface 300 which comprises the table 330 of package pin identifiers 320 and device pin identifiers 310 for the devices 210 comprising the package 200 to be tested by the test system 100 is provided to the user. Block 410 then transfers control to block 420.

In block 420, the user enters and/or changes entries in the table 330 of package pin identifiers 320 vs. device pin identifiers 310 for the devices 210 comprising the package 200 to be tested by the test system 100 via inputs to the graphical user interface 300. Block 420 then transfers control to block 430.

In block 430, a file comprising the contents of the table 330 of package pin identifiers 320 vs. device pin identifiers 310 for the devices 210 comprising the package 200 to be tested by the test system 100 is created. Block 430 then transfers control to block 440.

In block 440, new software test program 115 source code is created. The new software test program 115 source code comprises the version of the file created in block 430 which includes the contents of the version of the table 330 whose data was entered in block 420 for the package 200 to be tested by the test system 100. Block 440 then terminates the process.

In a representative embodiment, the test manager module 140 activates device A test program 110a to perform the tests specified in that program on the first device 210a in package 200 (identified in FIG. 1 as the unit under test 160). As an example, device A test program 110a could direct that a stimulus signal be applied to the device pin 220 identified as device pin identifier 310 DP1 of the first device 210a and detect a response signal at the device pin 220 identified as device pin identifier 310 DP2 of the first device 210a. Device A test program 110a then passes the command to apply the stimulus signal to the device pin 220 identified as device pin identifier 310 DP1 of the first device 210a and to expect a response signal at the device pin 220 identified as device pin identifier 310 DP2 of the first device 210a to the test manager module 140. The test manager module 140 translates the device pin identifier assignments of device A test program 110a into the package pin identifier 320 assignments for the first device 210a. To perform this translation, the test manager module 140 uses pin identifier translation module 150 to translate device pin identifier 310 DP1 into package pin identifier 320 PP1 and to translate device pin identifier 310 DP2 into package pin identifier 320 PP5, wherein the contents of the pin identifier translation module 150 were obtained from user inputs to the table 330 of FIG. 3. The test manager module 140 then proceeds to connect the appropriate tester resources 130 to the pins identified as package pin identifiers 320 PP1 and PP5 on the unit under test 160 which in this case is package 200. The appropriate stimulus signal from the appropriate tester resource 130 is applied to package pin 230 identified as package pin identifier 320 PP1, and the corresponding response signal is received from the package pin 230 identified as package pin identifier 320 PP5. The response signal is received by the test manager module 140. Test manager module 140 uses the pin identifier translation module 150 to translate package pin identifier 320 PP5 back into device pin identifier 310 DP2. Following this translation, the test manager module 140 passes the response signal to the device A test program 110a for disposition (analysis, storage, etc.).

Once device A test program 110a has completed its programmed tasks for tests on the first device 210a, the test manager module 140 again activates device A test program 110a to perform the tests specified in that program on the second device 210b in package 200. Device A test program 110a then could direct that a stimulus signal be applied to the device pin 220 identified as device pin identifier 310 DP1 of the second device 210b and detect a response signal at the device pin 220 identified as device pin identifier 310 DP2 of the second device 210b. Device A test program 110a then passes the command to apply the stimulus signal to the device pin 220 identified as device pin identifier 310 DP1 of the second device 210b and to expect a response signal at the device pin 220 identified as device pin identifier 310 DP2 of the second device 210b to the test manager module 140. The test manager module 140 translates the device pin identifier assignments of device A test program 110a into the package pin identifier 320 assignments for the second device 210b. To perform this translation, the test manager module 140 uses pin identifier translation module 150 to translate device pin identifier 310 DP1 into package pin identifier 320 PP2 and to translate device pin identifier 310 DP2 into package pin identifier 320 PP5, wherein the contents of the pin identifier translation module 150 were obtained from user inputs to the table 330 of FIG. 3. The test manager module 140 then proceeds to connect the appropriate tester resources 130 to the pins identified as package pin identifiers 320 PP2 and PP5 on the unit under test 160 which in this case is package 200. The appropriate stimulus signal from the appropriate tester resource 130 is applied to package pin 230 identified as package pin identifier 320 PP2, and the corresponding response signal is received from the package pin 230 identified as package pin identifier 320 PP5. The response signal is received by the test manager module 140. Test manager module 140 uses the pin identifier translation module 150 to translate package pin identifier 320 PP5 back into device pin identifier 310 DP2. Following this translation, the test manager module 140 passes the response signal to the device A test program 110a for disposition (analysis, storage, etc.).

Once device A test program 110a has completed its programmed tasks for tests on the second device 210b, the test manager module 140 again activates device A test program 110a to perform the tests specified in that program on the third device 210c in package 200. Device A test program 110a then could direct that a stimulus signal be applied to the device pin 220 identified as device pin identifier 310 DP1 of the third device 210c and detect a response signal at the device pin 220 identified as device pin identifier 310 DP2 of the third device 210c. Device A test program 110a then passes the command to apply the stimulus signal to the device pin 220 identified as device pin identifier 310 DP1 of the third device 210c and to expect a response signal at the device pin 220 identified as device pin identifier 310 DP2 of the third device 210c to the test manager module 140. The test manager module 140 translates the device pin identifier assignments of device A test program 110a into the package pin identifier 320 assignments for the third device 210c. To perform this translation, the test manager module 140 uses pin identifier translation module 150 to translate device pin identifier 310 DP1 into package pin identifier 320 PP3 and to translate device pin identifier 310 DP2 into package pin identifier 320 PP6, wherein the contents of the pin identifier translation module 150 were obtained from user inputs to the table 330 of FIG. 3. The test manager module 140 then proceeds to connect the appropriate tester resources 130 to the pins identified as package pin identifiers 320 PP3 and PP6 on the unit under test 160 which in this case is package 200. The appropriate stimulus signal from the appropriate tester resource 130 is applied to package pin 230 identified as package pin identifier 320 PP3, and the corresponding response signal is received from the package pin 230 identified as package pin identifier 320 PP6. The response signal is received by the test manager module 140. Test manager module 140 uses the pin identifier translation module 150 to translate package pin identifier 320 PP6 back into device pin identifier 310 DP2. Following this translation, the test manager module 140 passes the response signal to the device A test program 110a for disposition (analysis, storage, etc.).

Once device A test program 110a has completed its programmed tasks for tests on the third device 210c, the test manager module 140 now activates device B test program 110b to perform the tests specified in that program on the fourth device 210d in package 200. Device B test program 110b then could direct that a stimulus signal be applied to the device pin 220 identified as device pin identifier 310 DP3 of the fourth device 210d and detect a response signal at the device pin 220 identified as device pin identifier 310 DP4 of the fourth device 210d. Device B test program 110b then passes the command to apply the stimulus signal to the device pin 220 identified as device pin identifier 310 DP3 of the fourth device 210d and to expect a response signal at the device pin 220 identified as device pin identifier 310 DP4 of the fourth device 210d to the test manager module 140. The test manager module 140 translates the device pin identifier assignments of device B test program 110b into the package pin identifier 320 assignments for the fourth device 210d. To perform this translation, the test manager module 140 uses pin identifier translation module 150 to translate device pin identifier 310 DP3 into package pin identifier 320 PP4 and to translate device pin identifier 310 DP4 into package pin identifier 320 PP7, wherein the contents of the pin identifier translation module 150 were obtained from user inputs to the table 330 of FIG. 3. The test manager module 140 then proceeds to connect the appropriate tester resources 130 to the pins identified as package pin identifiers 320 PP4 and PP7 on the unit under test 160 which in this case is package 200. The appropriate stimulus signal from the appropriate tester resource 130 is applied to package pin 230 identified as package pin identifier 320 PP4, and the corresponding response signal is received from the package pin 230 identified as package pin identifier 320 PP7. The response signal is received by the test manager module 140. Test manager module 140 uses the pin identifier translation module 150 to translate package pin identifier 320 PP7 back into device pin identifier 310 DP4. Following this translation, the test manager module 140 passes the response signal to the device B test program 110b for disposition (analysis, storage, etc.).

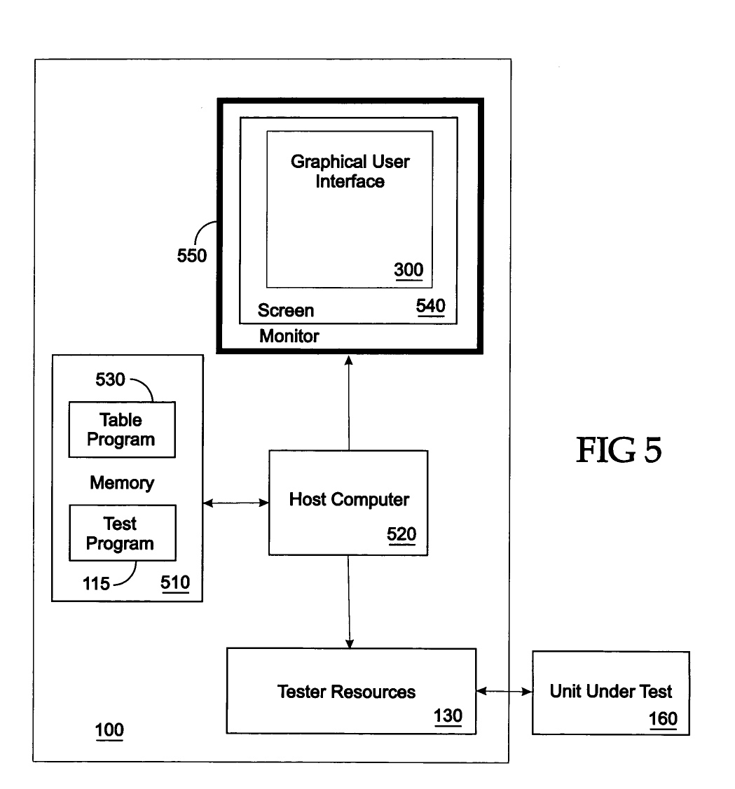

FIG. 5 is a drawing of another block diagram of the test system 100 as described in various representative embodiments. In FIG. 5, the test program 115 is stored in memory 510, as well as other files and/or programs as necessary. The stored test program 115 is loaded into a host computer 520 and executed in order to test the unit under test 160. As in FIG. 1, the executed test program 115 assigns and controls tester resources 130 during the test of the unit under test 160.

To create and/or modify the table 330, a table creation/modification program 530, also referred to herein as a table program 530, can be loaded into the host computer 520 and executed in order to create and/or change the entries in the table 330. In creating/changing the table 330, the table 330 is displayed on the graphical user interface 300 on a screen 540 of a monitor 550.

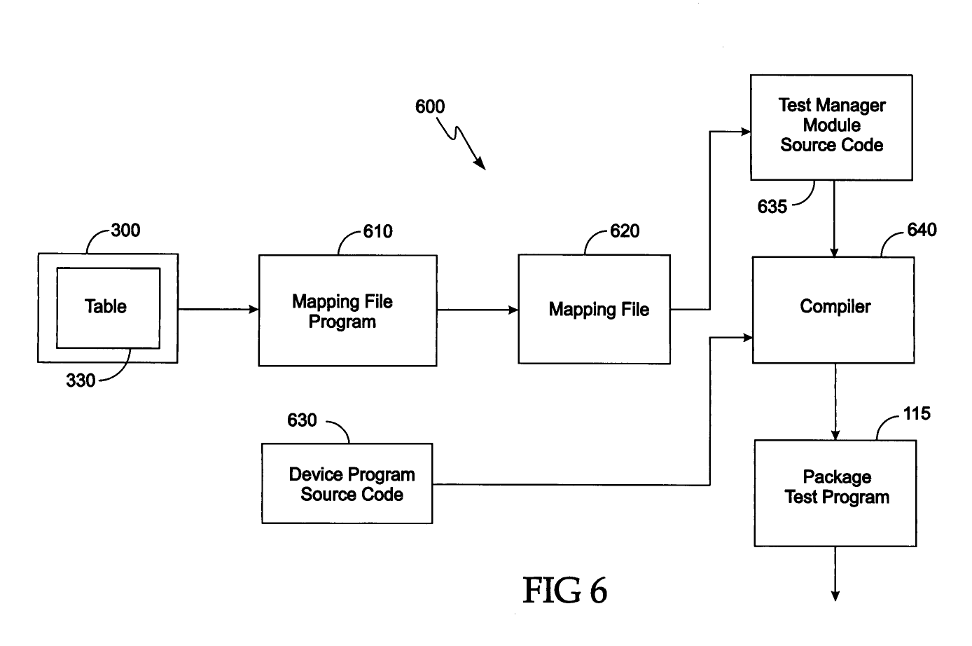

FIG. 6 is a drawing of a block diagram of a component configuration 600 used in creating a package test program 115 as described in various representative embodiments. In FIG. 6, the table 330 is created using the graphical user interface 300. A mapping file 620 can then be created via a mapping file program 610. However, other methods could be used to create the table 330 and/or the mapping file 620 such as hand coding appropriate device pin identifiers 310 into package pin identifiers 320 into the table 330 or directly into the mapping file 620. The test manager module source code 635 with input from the mapping file 620 can be compiled with the device program source code 630 by a compiler 640 to create the package test program 115. Device test program files 110 for multiple device test programs 110 could be similarly included using appropriate device program source code 630 as needed for the particular electronic package 200 to be tested. In FIG. 6, any necessary linking steps are assumed to have been completed in conjunction with the compilation of the compiler 640. In the configuration of FIG. 6, remapping of the device pin identifiers 310 to the appropriate package pin identifiers 320, thereby redirecting tester resources 130 from the device pin 220 to the appropriate package pin 230, could be effected by the use of “#define” statements in the package test program 115. In a representative embodiment, the mapping file 620 could be a header file that is included directly in the package test program 115 at compilation.

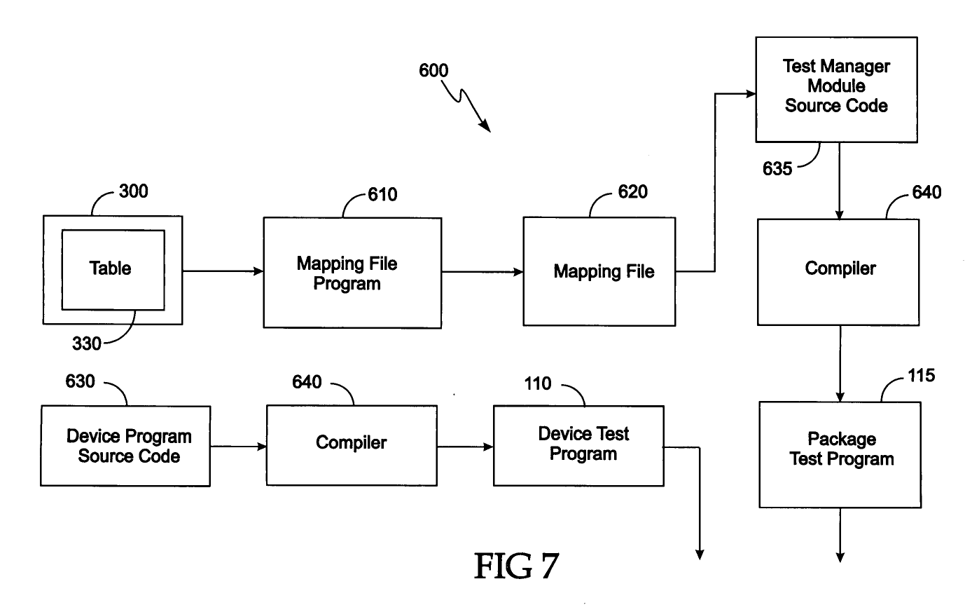

FIG. 7 is a drawing of a block diagram of another component configuration 600 used in creating a package test program 115 as described in various representative embodiments. In FIG. 7, the table 330 is created using the graphical user interface 300. The mapping file 620 can then be created via the mapping file program 610. As stated above, other methods could be used to create the table 330 and/or the mapping file 620 such as hand coding appropriate device pin identifiers 310 into package pin identifiers 320 into the table 330 or directly into the mapping file 620. The test manager module source code 635 with input from the mapping file 620 can be compiled with the device program source code 630 by a compiler 640 to create the package test program 115. In FIG. 7, any necessary linking steps are assumed to have been completed in conjunction with the compilation of the compiler 640. In the alternative embodiment of FIG. 7, the device program source code 630 is separately compiled (and linked) by compiler 640 to create the device test program 110. Device test program files 110 for multiple device test programs 110 could be similarly created using appropriate device program source code 630 as needed for the particular electronic package 200 to be tested. Remapping of the device pin identifiers 310 to the appropriate package pin identifiers 320, thereby redirecting tester resources 130 from the device pin 220 to the appropriate package pin 230, could be effected by the use of “#define” statements or other means at the time the package test program 115 calls the device test program 110. In a representative embodiment, the mapping file 620 could be a header file that is included directly in the package test program 115 at compilation.

As is the case, in many data-processing products, the systems described above may be implemented as a combination of hardware and software components. Moreover, the functionality required for use of the representative embodiments may be embodied in computer-readable media (such as floppy disks, conventional hard disks, DVDs, CD-ROMs, Flash ROMs, nonvolatile ROM, and RAM) to be used in programming an information-processing apparatus (e.g., the host computer 520 among others) to perform in accordance with the techniques so described.

The term “program storage medium” is broadly defined herein to include any kind of computer memory such as, but not limited to, floppy disks, conventional hard disks, DVDs, CD-ROMs, Flash ROMs, nonvolatile ROM, and RAM.

Advantages of the representative embodiments disclosed herein include a method and tool which reassigns tester resources for multi-chip packages and other packaged devices without requiring modification to the test program written for the wafer test. Generating pin mapping files based on user input removes the need to change the wafer test programs.

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. A method, comprising:
creating a mapping file; and
creating a package test program for testing an electronic package, wherein the electronic package comprises a device, wherein the package test program comprises is created from code for a device test program for testing the device and source code from the mapping file, wherein the device test program source code comprises at least one reference to at least one device pin identifier, wherein each device pin identifier identifies an associated device pin on the device, wherein each identified device pin is attached to an associated package pin on the electronic package, wherein each package pin is identified by a package pin identifier, wherein the mapping file redefines each device pin identifier in the device test program source code to be the associated package pin identifier in the package test program, and wherein at least one instruction in the package test program created from the device test program source code is configured to attach a tester resource to one of the package pins, and to appropriately activate the tester resource.

2. The method as recited in claim 1, wherein the method step for creating the package test program comprises: compiling the package test program.

3. The method as recited in claim 2, wherein the mapping file is a header file that is included during the method step for compiling the package test program.

4. The method as recited in claim 1, wherein the electronic package comprises an additional device, wherein the package test program comprises source code for an additional device test program for testing the additional device, wherein the additional device test program source code comprises at least one reference to at least one additional device pin identifier, wherein each device pin identifier identifies an associated additional device pin on the additional device, wherein each identified additional device pin is attached to an associated additional package pin on the electronic package, wherein each additional package pin is identified by an additional package pin identifier, wherein the mapping file redefines each additional device pin identifier in the additional device test program source code to be the associated additional package pin identifier in the package test program, and wherein at least one instruction in the package test program created using the additional device test program source code is configured to attach one of the tester resources to one of the additional package pins, and to appropriately activate the tester resource.

5. The method as recited in claim 1, wherein the electronic package comprises an additional device of the same type, wherein the package test program reuses the device test program source code for testing the additional device, wherein each identified device pin for the additional device is attached to an associated additional package pin on the electronic package, wherein each additional package pin is identified by an additional package pin identifier, wherein the mapping file redefines each device pin identifier for the additional device in the device test program source code to be the associated additional package pin identifier in the package test program, and wherein at least one instruction in the package test program created using the device test program source code for the additional device is configured to attach one of the tester resources to one of the additional package pins, and to appropriately activate the tester resource.

6. The method as recited in claim 1, wherein the method step for creating the mapping file comprises:
displaying a table on a graphical user interface, wherein the table comprises multiple cells organized in rows and columns;
entering data into the cells, wherein entries in the cells provide a mapping between the package pin identifiers and the device pin identifiers for each device in the electronic package; and
creating the mapping file comprising information in the table.

7. The method as recited in claim 6, wherein the mapping file is created as a header file which is included in the package test program when the package test program is compiled.

8. A method, comprising:
creating a mapping file;
creating a device test program for testing the device; and
creating a package test program for testing an electronic package, wherein the electronic package comprises a device, wherein the package test program is created from source code from the mapping file, wherein the device test program source code comprises at least one reference to at least one device pin identifier, wherein each device pin identifier identifies an associated device pin on the device, wherein each identified device pin is attached to an associated package pin on the electronic package, wherein each package pin is identified by a package pin identifier, wherein the mapping file redefines each device pin identifier in the device test program to be the associated package pin identifier in the package test program, and wherein at least one instruction in the device test program is configured to attach a tester resource to one of the package pins after translation from the device pin identifier to the associated package pin identifier, and to appropriately activate the tester resource.

9. The method as recited in claim 8, wherein the method step for creating the package test program comprises:
compiling the package test program.

10. The method as recited in claim 9, wherein the mapping file is a header file that is included during the method step for compiling the package test program.

11. The method as recited in claim 8, further comprising:
creating an additional device test program for testing an additional device, wherein the electronic package comprises the additional device, wherein the additional device test program source code comprises at least one reference to at least one additional device pin identifier, wherein each device pin identifier identifies an associated additional device pin on the additional device, wherein each identified additional device pin is attached to an associated additional package pin on the electronic package, wherein each additional package pin is identified by an additional package pin identifier, wherein the mapping file redefines each device pin identifier in the additional device test program to be the associated package pin identifier in the package test program, and wherein at least one instruction in the additional device test program is configured to attach a tester resource to one of the package pins after translation from the device pin identifier to the associated package pin identifier, and to appropriately activate the tester resource.

12. The method as recited in claim 8, wherein the electronic package comprises an additional device of the same type, wherein the package test program reuses the device test program for testing the additional device, wherein each identified device pin for the additional device is attached to an associated additional package pin on the electronic package, wherein each additional package pin is identified by an additional package pin identifier, wherein the mapping file redefines each device pin identifier in the additional device test program to be the associated package pin identifier in the package test program, and wherein at least one instruction in the additional device test program is configured to attach a tester resource to one of the package pins after translation from the device pin identifier to the associated package pin identifier, and to appropriately activate the tester resource.

13. The method as recited in claim 8, wherein the method step for creating the mapping file comprises:
displaying a table on a graphical user interface, wherein the table comprises multiple cells organized in rows and columns;
entering data into the cells, wherein entries in the cells provide a mapping between the package pin identifiers and the device pin identifiers for each device in the electronic package; and
creating the mapping file comprising information in the table.

14. The method as recited in claim 13, wherein the mapping file is created as a header file which is included in the package test program when the package test program is compiled.

15. A method, comprising:
providing a graphical user interface;
displaying a table on the graphical user interface;
associating each cell of a first column with a different package pin on an electronic package, wherein each package pin is identified by a package pin identifier, wherein the electronic package comprises at least one device, wherein each device has at least one device pin, wherein at least one of the device pins is attached to one of the package pins, and wherein each attached device pin is identified by a device pin identifier;
entering into each cell of the first column the package pin identifier which identifies the package pin associated with that cell;
for each device, adding a column of cells to the table;
for each device pin of each device attached to one of the package pins, entering the device pin identifier into the cell lying in the column associated with that device and lying in the row of the first column cell containing the package pin identifier of the package pin to which the device pin is attached; and
creating a mapping file from the contents of the table.

16. The method as recited in claim 15, wherein the mapping file is created as a header file, wherein the header file is configured for inclusion in a package test program when the package test program is compiled and wherein the package test program is configured for testing the devices in the electronic package.
